(19) United States
(12) Patent Application Publication
(10) Pub. No.: US 2026/0324291 A1
(43) Pub. Date: Oct. 15, 2026

(54) WAFER AND MAGNETIC SENSOR MANUFACTURING METHOD

(71) Applicant: TDK Corporation, Tokyo (JP)

(72) Inventor: Toshihide SUTO, Tokyo (JP)

(73) Assignee: TDK Corporation, Tokyo (JP)

(21) Appl. No.: 19/467,328

(22) Filed: Feb. 2, 2026

(30) Foreign Application Priority Data
Feb. 5, 2025 (JP) 2025-017715

(51) Int. Cl. H10N 50/01; H10N 50/10; H10N 59/00

(52) U.S. Cl. CPC H10N 50/01; H10N 50/10; H10N 59/00

(57) ABSTRACT

A wafer includes a plurality of MR elements, a plurality of arrays, and a plurality of dies. Each of the plurality of MR elements includes a magnetization pinned layer. The directions of magnetization of the magnetization pinned layers are defined for each array. The plurality of dies are arranged at a first pitch. The arrays are arranged at a second pitch. The MR elements are arranged at a third pitch. The dies and the arrays are arranged in a manner that the second pitch is not larger than the first pitch. The arrays and the MR elements are arranged in a manner that the third pitch is not larger than the second pitch.

### CROSS REFERENCE TO RELATED APPLICATIONS

This application claims the benefit of Japanese Priority Patent Application No. 2025-017715 filed on Feb. 5, 2025, the entire contents of which are incorporated herein by reference.

### BACKGROUND

The disclosure relates to a wafer to be used for manufacturing magnetic sensors and a magnetic sensor manufacturing method.

In recent years, magnetic sensors have been used for a variety of applications. Examples of known magnetic sensors include one that uses spin-valve magnetoresistive elements provided on a substrate. The spin-valve magnetoresistive element includes a magnetization pinned layer having magnetization whose direction is fixed, a free layer having magnetization whose direction is variable according to a magnetic field, and a gap layer provided between the magnetization pinned layer and the free layer.

The magnetic sensor includes a bridge circuit configured to detect a detection-target magnetic field to generate a detection signal. In the magnetic sensor using spin-valve magnetoresistive elements, the bridge circuit is configured by using a plurality of types of magnetoresistive elements having respective magnetization pinned layers each having magnetization whose direction is fixed differently.

JP 2018-517128 T and the Specification of Chinese Patent Application Publication No. 102208530 each disclose a magnetic sensor configured by using a plurality of types of magnetoresistive elements having respective ferromagnetic reference layers each having magnetization whose direction is fixed differently, and a manufacturing method of this magnetic sensor. In each of JP 2018-517128 T and the Specification of Chinese Patent Application Publication No. 102208530, for the manufacturing of the magnetic sensor, a wafer in which the plurality of types of magnetoresistive elements are formed in different areas is used. The direction of the magnetization of the ferromagnetic reference layer of each of the plurality of types of magnetoresistive elements is directly determined by using a laser beam and an electromagnet.

To reduce the manufacturing cost of such a magnetic sensor, reducing a lead time is important. Especially for a magnetic sensor including a plurality of types of magnetoresistive elements having respective magnetization pinned layers each having magnetization whose direction is fixed differently, an idea is needed to efficiently fix the directions of the magnetization of the magnetization pinned layers in a process of manufacturing the magnetic sensor. However, such an idea is not studied sufficiently heretofore.

### SUMMARY

A wafer according to one embodiment of the disclosure is used for manufacturing of a plurality of magnetic sensors. A wafer of the disclosure includes: a plurality of magnetoresistive elements arranged regularly; a plurality of arrays each including some magnetoresistive elements of the plurality of magnetoresistive elements and arranged regularly; and a plurality of dies sectioned regularly to correspond to the plurality of respective magnetic sensors and each including some arrays of the plurality of arrays. Each of the plurality of magnetoresistive elements includes a magnetization pinned layer having magnetization whose direction is fixed, a free layer having magnetization whose direction is variable according to an applied magnetic field, and a gap layer arranged between the magnetization pinned layer and the free layer. The directions of the magnetization of the magnetization pinned layers are defined for each of the plurality of arrays. The plurality of dies are arranged at a first pitch. The some arrays are arranged at a second pitch in each of the plurality of dies and electrically connected to configure a bridge circuit. The some magnetoresistive elements are arranged at a third pitch in each of the plurality of arrays and electrically connected to each other. The plurality of dies and the some arrays are arranged in a manner that the second pitch is not larger than the first pitch. The some arrays and the some magnetoresistive elements are arranged in a manner that the third pitch is not larger than the second pitch.

A magnetic sensor manufacturing method according to one embodiment of the disclosure is a manufacturing method of manufacturing a plurality of magnetic sensors by using a wafer. The wafer includes: a plurality of magnetoresistive elements arranged regularly; a plurality of arrays each including some magnetoresistive elements of the plurality of magnetoresistive elements and arranged regularly; and a plurality of dies sectioned regularly to correspond to the plurality of respective magnetic sensors and each including some arrays of the plurality of arrays. Each of the plurality of magnetoresistive elements includes a magnetization pinned layer having magnetization whose direction is fixed, a free layer having magnetization whose direction is variable according to an applied magnetic field, and a gap layer arranged between the magnetization pinned layer and the free layer. The directions of the magnetization of the magnetization pinned layers are defined for each of the plurality of arrays. The plurality of dies are arranged at a first pitch. The some arrays are arranged at a second pitch in each of the plurality of dies and electrically connected to configure a bridge circuit. The some magnetoresistive elements are arranged at a third pitch in each of the plurality of arrays and electrically connected to each other. The plurality of dies and the some arrays are arranged in a manner that the second pitch is not larger than the first pitch. The some arrays and the some magnetoresistive elements are arranged in a manner that the third pitch is not larger than the second pitch.

The magnetic sensor manufacturing method according to one embodiment of the disclosure includes: producing the wafer; dicing the plurality of dies from the wafer to produce a plurality of chips; and producing the plurality of magnetic sensors from the plurality of chips. The producing of the wafer includes element formation of forming the plurality of magnetoresistive elements and the plurality of arrays and forming wiring for connecting the plurality of magnetoresistive elements. The element formation includes forming a plurality of initial magnetoresistive elements each including an initial magnetization pinned layer to later be the magnetization pinned layer and the free layer and fixation of fixing a direction of the magnetization of the initial magnetization pinned layer of each of the plurality of initial magnetoresistive elements.

Objects, features, and advantages of the disclosure appear more fully from the following description.

### BRIEF DESCRIPTION OF THE DRAWINGS

The accompanying drawings are included to provide an understanding of the disclosure and are incorporated in and constitute a part of this specification. The

drawings illustrate example embodiments and, together with the specification, serve to explain the principles of the technology.

FIG. 1 is a circuit diagram showing a circuit configuration of a magnetic sensor in a first example embodiment of the disclosure.

FIG. 2 is a perspective view showing a part of the magnetic sensor in the first example embodiment of the disclosure.

FIG. 3 is a flowchart showing a manufacturing method of a magnetic sensor according to the first example embodiment of the disclosure.

FIG. 4 is a flowchart showing a producing method of a wafer according to the first example embodiment of the disclosure.

FIG. 5 is a plan view showing a wafer according to the first example embodiment of the disclosure.

FIG. 6 is a plan view showing a section of the wafer according to the first example embodiment of the disclosure.

FIG. 7 is a plan view showing a plurality of dies included in an irradiation-target region of the wafer according to the first example embodiment of the disclosure.

FIG. 8 is a plan view showing two dies of the wafer according to the first example embodiment of the disclosure.

FIG. 9 is an explanatory view showing irradiation-target regions in first fixation of fixation in the first example embodiment of the disclosure.

FIG. 10 is an explanatory view showing the irradiation-target regions in second fixation of the fixation in the first example embodiment of the disclosure.

FIG. 11 is an explanatory diagram showing irradiation-target regions in a second example embodiment of the disclosure.

FIG. 12 is an explanatory view showing irradiation-target regions in a third example embodiment of the disclosure.

FIG. 13 is a plan view showing one die in a fourth example embodiment of the disclosure.

FIG. 14 is a plan view showing one die in a fifth example embodiment of the disclosure.

FIG. 15 is a circuit diagram showing a circuit configuration of a magnetic sensor in a sixth example embodiment of the disclosure.

FIG. 16 is a plan view showing one die in the sixth example embodiment of the disclosure.

FIG. 17 is a circuit diagram showing a circuit configuration of a magnetic sensor in a seventh example embodiment of the disclosure.

FIG. 18 is a plan view showing one die in the seventh example embodiment of the disclosure.

### DETAILED DESCRIPTION

One object of the disclosure is to provide a wafer with which the directions of magnetization of magnetization pinned layers can be fixed efficiently and a magnetic sensor manufacturing method using this wafer.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions.

### First Example Embodiment

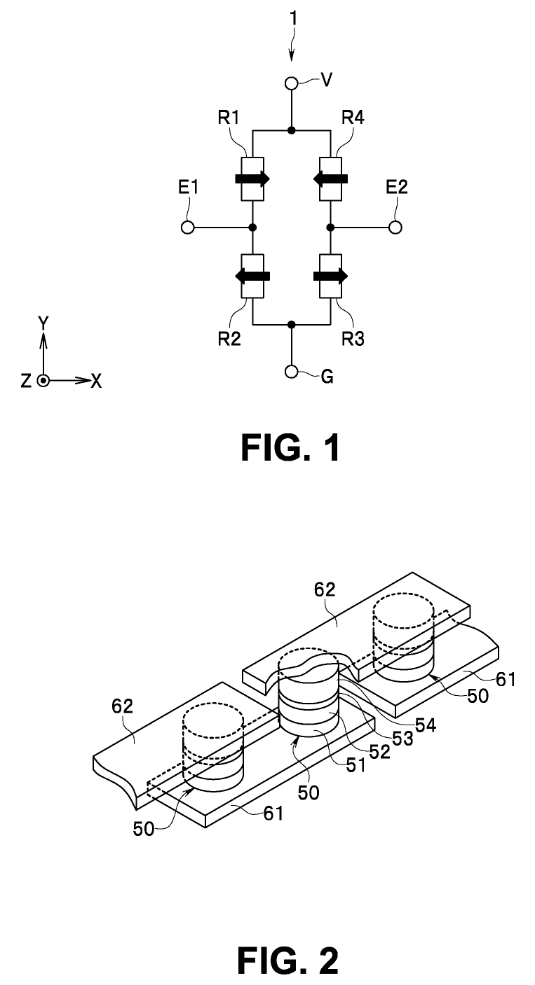

First, with reference to FIG. 1 and FIG. 2, an example of a configuration of a magnetic sensor 1 manufactured by a magnetic sensor manufacturing method according to a first example embodiment of the disclosure will be described. FIG. 1 is a circuit diagram showing a circuit configuration of the magnetic sensor 1. FIG. 2 is a perspective view showing a part of the magnetic sensor 1.

The magnetic sensor 1 includes a power supply port V, a ground port G, at least one output port, and at least two resistor sections. In the example embodiment, in particular, the magnetic sensor 1 includes two output ports E1 and E2 as the at least one output port and four resistor sections R1, R2, R3, and R4 as the at least two resistor sections. A voltage or an electric current having a specific magnitude is applied to the power supply port V. The ground port G is connected to the ground.

The resistor section R1 is provided between the power supply port V and the output port E1 in the circuit configuration. The resistor section R2 is provided between the ground port G and the output port E1 in the circuit configuration. The resistor section R3 is provided between the ground port G and the output port E2 in the circuit configuration. The resistor section R4 is provided between the power supply port V and the output port E2 in the circuit configuration. Note that, in the application, the expression "in the (a) circuit configuration" is used to indicate a layout in a circuit diagram, not a layout in a physical configuration.

The magnetic sensor 1 further includes a plurality of magnetoresistive elements (hereinafter, referred to as MR elements) 50. Each of the resistor sections R1 to R4 includes two or more MR elements 50, which are some MR elements 50 of the plurality of MR elements 50.

The magnetic sensor 1 further includes a plurality of lower electrodes 61 and a plurality of upper electrodes 62 for electrically connecting the plurality of MR elements 50. The plurality of lower electrodes 61 and the plurality of upper electrodes 62 contain a conductive material. The plurality of lower electrodes 61 are arranged on a substrate not shown. The plurality of MR elements 50 are arranged on the plurality of lower electrodes 61. The plurality of upper electrodes 62 are arranged on the plurality of MR elements 50.

A method of connecting the plurality of MR elements 50 to the plurality of lower electrodes 61 and the plurality of upper electrodes 62 is as follows. As shown in FIG. 2, each of the lower electrodes 61 has an elongated shape. Every two lower electrodes 61 that are adjacent to each other in the longitudinal direction of the lower electrodes 61 have a gap therebetween. Each MR element 50 is arranged in the vicinity of each of both longitudinal ends on the upper surface of the corresponding lower electrode 61. Each upper electrode 62 has an elongated shape, and electrically connects the two adjacent MR elements 50 arranged on two lower electrodes 61 that are adjacent to each other in the longitudinal direction of the lower electrodes 61. In such a manner, the plurality of MR elements 50 are connected in series.

Here, focus on any one MR element 50 of the plurality of MR elements 50. The MR element 50 is a spin-valve MR element. The MR element 50 includes a magnetization pinned layer 52 having magnetization whose direction is fixed, a free layer 54 having magnetization whose direction is variable according to the direction and magnitude of an applied magnetic field, and a gap layer 53 arranged between the magnetization pinned layer 52 and the free layer 54. The MR element 50 may be a TMR (tunneling magnetoresistive) element or a GMR (giant magnetoresistive) element. In the TMR element, the gap layer 53 is a tunnel barrier layer. In the GMR element, the gap layer 53 is a nonmagnetic conductive layer. The resistance of the MR element 50 changes with the angle that the direction of the magnetization of the free layer 54 forms with respect to the magnetization direction of the magnetization pinned layer 52. The resistance of the MR element 50 is at its minimum value when the foregoing angle is 0°, and at its maximum value when the foregoing angle is 180°.

The magnetization pinned layer 52 contains a magnetic material such as CoFe, CoFeB, or CoNiFe. The magnetization pinned layer 52 may further contain a non-magnetic material such as Ru. The free layer 54 contains a magnetic material such as CoFe, CoFeB, NiFe, or CoNiFe.

The MR element 50 further includes an antiferromagnetic layer 51. The antiferromagnetic layer 51, the magnetization pinned layer 52, the gap layer 53, and the free layer 54 are stacked on the lower electrode 61 in this order. The antiferromagnetic layer 51 contains an antiferromagnetic material such as IrMn or PtMn, and is in exchange coupling with the magnetization pinned layer 52 to thereby fix the direction of the magnetization of the magnetization pinned layer 52. Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. When the magnetization pinned layer 52 is a self-pinned layer, the antiferromagnetic layer 51 may be omitted.

Note that the layers 51 to 54 of each of the MR elements 50 may be arranged in the reverse order to that shown in FIG. 2.

The free layer 54 may have or need not have a magnetization easy axis. The magnetization easy axis of the free layer 54 can be set by forming a planar shape elongated in one direction or providing a magnetic field generator, such as a magnet, that applies a bias magnetic field.

Next, the directions of magnetization of the magnetization pinned layers 52 will be described with reference to FIG. 1. The magnetization of the magnetization pinned layer 52 of each of the plurality of MR elements 50 in the resistor sections R1 and R3 contains a component in a first magnetization direction. The magnetization of the magnetization pinned layer 52 of each of the plurality of MR elements 50 in the resistor sections R2 and R4 contains a component in a second magnetization direction opposite to the first magnetization direction. In FIG. 1, the plurality of arrows that are illustrated to overlap the resistor sections R1 and R3 represent the first magnetization direction, and the plurality of arrows illustrated to overlap the resistor sections R2 and R4 represent the second magnetization direction.

Note that, when the magnetization of the magnetization pinned layer 52 contains a component in a specific magnetization direction, the component in the specific magnetization direction may be the main component of the magnetization of the magnetization pinned layer 52. Alternatively, the magnetization of the magnetization pinned layer 52 need not contain a component in a direction orthogonal to the specific magnetization direction. In the example embodiment, when the magnetization of the magnetization pinned layer 52 contains the component in the specific magnetization direction, the direction of the magnetization of the magnetization pinned layer 52 is the same or substantially the same as the specific magnetization direction.

Here, as shown in FIG. 1, an X direction, a Y direction, and a Z direction are defined. The X direction, the Y direction, and the Z direction are orthogonal to one another. The opposite directions to the X, Y, and Z directions will be referred to as −X, −Y, and −Z directions, respectively. In the example embodiment, in particular, a direction parallel to a stacking direction of the layers 51 to 54 and a direction from the layer 51 toward the layer 54 will be referred to as the Z direction.

In the example shown in FIG. 1, the first magnetization direction is the X direction, and the second magnetization direction is the −X direction. Note that the first magnetization direction is not limited to the X direction and may be the −X direction, the Y direction, or the −Y direction or may be a direction inclined with respect to each of the X direction and the Y direction.

The magnetic sensor 1 is configured so that the potential difference between the output ports E1 and E2 changes when at least one of the direction and the magnitude of a detection-target magnetic field of the magnetic sensor 1 changes. A signal corresponding to the potential of each of the output ports E1 and E2 or a signal corresponding to the potential difference between the output ports E1 and E2 has a correspondence with at least one of the direction and the magnitude of the detection-target magnetic field.

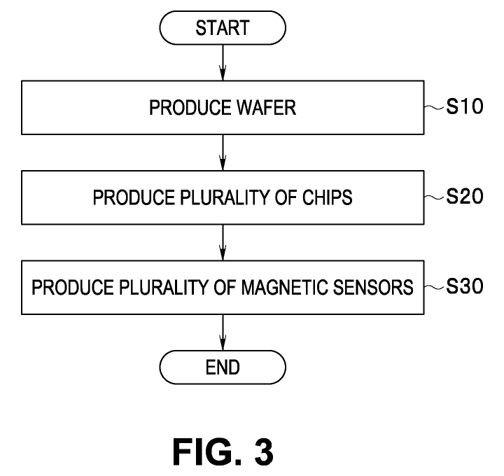

Next, a manufacturing method of the magnetic sensor 1 according to the example embodiment will be described with reference to FIG. 3. FIG. 3 is a flowchart showing a manufacturing method of the magnetic sensor 1 according to the example embodiment. Here, an overview of the manufacturing method of the magnetic sensor 1 will be described by taking a case of manufacturing a plurality of magnetic sensors 1 as an example.

The manufacturing method of magnetic sensors according to the example embodiment includes step S10 of producing a wafer to be used for manufacturing the plurality of magnetic sensors 1, step S20 of producing a plurality of chips from the wafer, and step S30 of producing the plurality of magnetic sensors 1 from the plurality of chips. In step S10 of producing the wafer, a plurality of dies regularly sectioned to correspond to the plurality of magnetic sensors 1 are formed. In step S20 of producing the plurality of chips, a plurality of dies are diced by wafer dicing, to thereby produce the plurality of chips. In step S30 of producing the plurality of magnetic sensors 1, each of the plurality of chips is placed in one package including a plurality of terminals, to thereby produce the plurality of magnetic sensors 1.

Next, step S10 of producing a wafer will be described in detail. Step S10 of producing the wafer includes element formation of forming the plurality of MR elements 50 and a plurality of arrays to be described later and wiring formation of forming wiring for connecting the plurality of MR elements 50. The wiring formation includes forming the plurality of lower electrodes 61, forming the plurality of upper electrodes 62, forming a plurality of first wirings connecting the resistor sections R1 to R4 to each other, and forming a plurality of second wirings for connecting the resistor sections R1 to R4 to electrode pads to be described later.

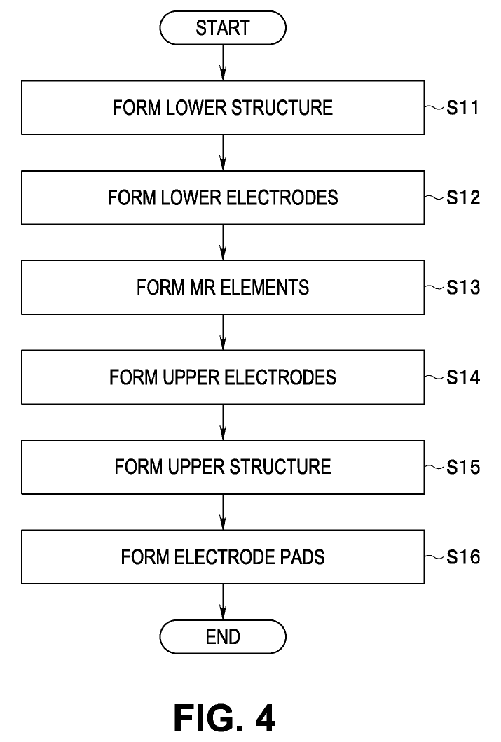

By focusing on one magnetic sensor 1, step S10 of producing a wafer will be described below. FIG. 4 is a flowchart showing step S10 of producing a wafer. In step S10 of producing a wafer, first, step S11 of forming a lower structure of each of the magnetic sensors 1 on a bare wafer is performed. The lower structure includes a plurality of components formed on the −Z-direction sides of the plurality of respective lower electrodes 61 of the magnetic sensor 1, and an insulating layer. The plurality of components may each be, for example, a soft magnetic layer formed of a soft magnetic material such as a plurality of yokes or at least one shield, may be a conductive layer formed of a conductive material such as a coil, or may be a passive element or an active element configuring a circuit of the magnetic sensor 1. Note that these components are not essential components of the magnetic sensor 1 and need not be provided.

Next, step S12 of forming the plurality of lower electrodes 61, element formation S13 of forming the plurality of MR elements 50 and the plurality of arrays to be described later, and step S14 of forming the plurality of upper electrodes. Each of steps S12 to S14 includes a plurality of sub-steps. The plurality of sub-steps may include forming an insulating layer not shown. The plurality of lower electrodes 61 may be completed before step S13 or may be completed after step S13. In the latter case, one or some of the sub-steps of step S12 may be performed during step S13 or after step S13.

In element formation S13, first, a plurality of initial MR elements to later become the plurality of MR elements 50 are formed. Each of the plurality of initial MR elements includes at least an initial magnetization pinned layer to later become the magnetization pinned layer 52, the free layer 54, and the gap layer 53. Each of the plurality of initial MR elements may further include the antiferromagnetic layer 51. The plurality of initial MR elements may be an integrated stacked film or may be stacked films individually patterned.

In element formation S13, next, fixation of fixing the direction of the magnetization of the initial magnetization pinned layer of each of the plurality of initial MR elements is performed. In the example embodiment, in particular, the fixation may fix the direction of the magnetization of the initial magnetization pinned layer by using laser light and an external magnetic field. The fixation may include first fixation of fixing the direction of magnetization of the initial magnetization pinned layer of each of the plurality of initial MR elements to later become the plurality of MR elements 50 of the resistor sections R1 and R3 and second fixation of fixing the direction of the magnetization of the initial magnetization pinned layer of each of the plurality of initial MR elements to later become the plurality of MR elements 50 of the resistor sections R2 and R4. The second fixation may be performed after the first fixation or may be performed before the first fixation.

In the first fixation, the plurality of initial MR elements are irradiated with a laser beam while an external magnetic field is applied thereto. When the initial MR elements include the antiferromagnetic layer 51, the irradiation of the laser light is performed so that the temperature of the plurality of initial MR elements irradiated with the laser light is equal to or higher than a blocking temperature of the antiferromagnetic layer 51. The temperature of the plurality of initial MR elements can be adjusted, for example, by the intensity and the pulse width of the laser light. After the irradiation of the laser light, when the temperature of the plurality of initial MR elements becomes lower than the blocking temperature, the direction of the magnetization of the initial magnetization pinned layer is fixed in the first magnetization direction (X direction).

In the first fixation, the direction of an external magnetic field to be applied to the initial magnetization pinned layers is set at such a direction that the directions of the magnetization of the initial magnetization pinned layers can be fixed in the first magnetization direction. As long as a requirement that the direction can be fixed in the first magnetization direction is satisfied, the direction of the external magnetic field to be applied to the initial magnetization pinned layers may be the same direction as the first magnetization direction or may be a direction different from the first magnetization direction. In the example embodiment, in particular, the direction of the external magnetic field may be the same direction as the first magnetization direction.

Similarly, in the second fixation, the plurality of initial MR elements are irradiated with laser light while an external magnetic field in a direction possible to fix the directions of the magnetization of the initial magnetization pinned layers in the second magnetization direction (−X direction) is applied thereto. Consequently, the directions of the magnetization of the initial magnetization pinned layers are fixed in the second magnetization direction.

When the plurality of initial MR elements are an integrated stacked film, the stacked film may be patterned, after the directions of the magnetization of the initial magnetization pinned layers are fixed, to form the plurality of MR elements 50 of the resistor sections R1 to R4. When the plurality of initial MR elements are individually patterned stacked films, the initial magnetization pinned layers become the magnetization pinned layers 52 by the directions of the magnetization of the initial magnetization pinned layers being fixed, and thereby the plurality of initial MR elements become the plurality of MR elements 50. By the plurality of MR elements 50 being formed, the plurality of arrays are formed.

In step S10 of producing a wafer, next, step S15 of forming an upper structure of each of the magnetic sensors 1 is performed. The upper structure includes a plurality of components formed on the Z-direction sides of the plurality of respective upper electrodes 62 of the magnetic sensor 1, and an insulating layer. The plurality of components may each be, for example, a soft magnetic layer formed of a soft magnetic material such as a plurality of yokes or at least one shield, may be a conductive layer formed of a conductive material such as a coil, or may be a passive element or an active element configuring a circuit of the magnetic sensor 1. Note that these components are not essential components of the magnetic sensor 1 and need not be provided.

Next, forming of a plurality of first wirings and forming of a plurality of second wirings are performed. Each of these steps includes a plurality of sub-steps. One or some of the plurality of sub-steps may be performed at the same time as step S12 or step S14. Next, step S16 of forming a plurality of electrode pads is performed. Each of the plurality of electrode pads includes the power supply port V, the ground port G, and four electrode pads corresponding to the output ports E1 and E2. By the plurality of electrode pads being formed, the wafer is completed.

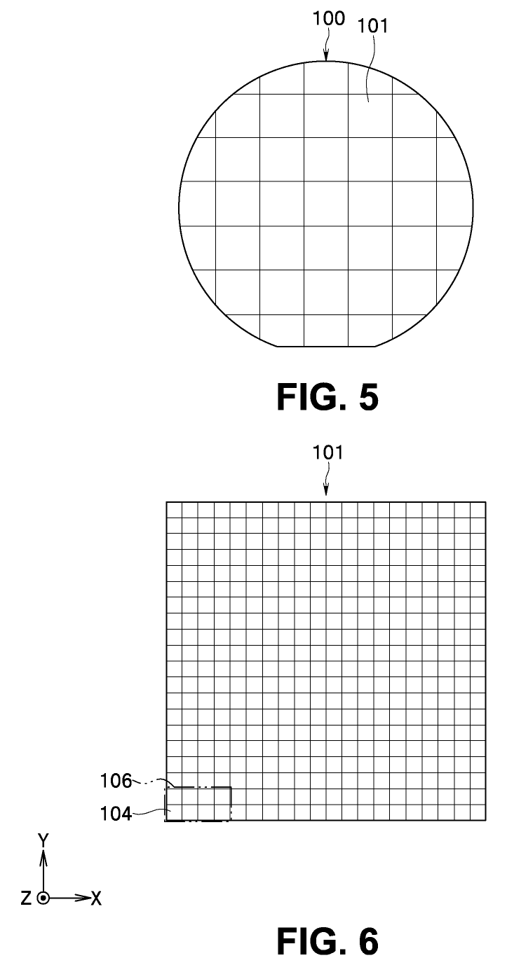

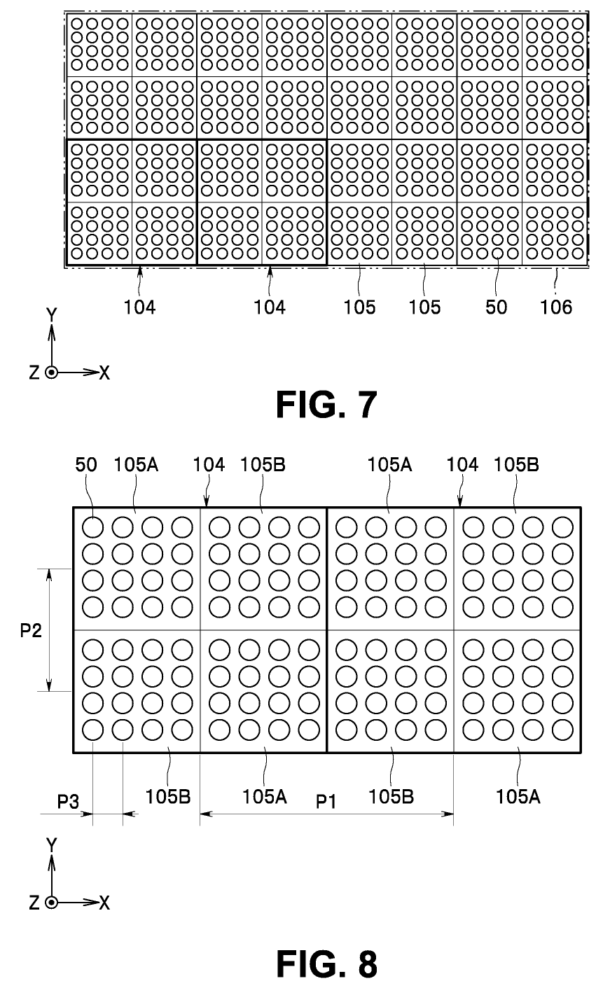

Next, a wafer according to the example embodiment will be described in detail with reference to FIG. 5 to FIG. 8. FIG. 5 is a plan view showing the wafer according to the example embodiment. FIG. 6 is a plan view showing a section of the wafer according to the example embodiment. FIG. 7 is a plan view showing a plurality of dies included in an irradiation-target region of the wafer according to the example embodiment. FIG. 8 is a plan view showing two dies of the wafer according to the example embodiment.

The wafer 100 according to the example embodiment includes the plurality of MR elements 50 arranged regularly, a plurality of arrays 105 each including some of the MR elements 50 of the plurality of MR elements 50 and also arranged regularly, and a plurality of dies 104 sectioned regularly to correspond to the plurality of respective magnetic sensors 1 and also each include some arrays 105 of the plurality of arrays 105. Here, the wafer 100 is divided into a plurality of rectangular sections 101. Arrangement of the plurality of dies 104, the plurality of arrays 105, and the plurality of MR elements 50 will be described below by focusing on one section 101.

As shown in FIG. 6, the plurality of dies 104 are arranged so that a plurality of the dies 104 are aligned in each of two directions orthogonal to each other. In FIG. 6, the X, Y, and Z directions are shown as in FIG. 1. The two directions orthogonal to each other may correspond to or need not correspond to the X direction and the Y direction. Description will be given below by taking, as an example, a case where the two directions orthogonal to each other are the X direction and the Y direction.

In FIG. 6 and FIG. 7, a reference numeral 106 indicates an irradiation-target region where the stack including the plurality of initial MR elements is irradiated with laser light at the same time in the fixation of element formation S13. The irradiation-target region 106 may be defined, by assuming that no mask to be described later is used, as a region of the stack irradiated with effective laser light. The “effective laser light” concretely means laser light having intensity capable of fixing the directions of the magnetization of the initial magnetization pinned layers of the initial MR elements in a desired direction.

The area of the irradiation-target region 106 may be larger than the area of the planar shape of each of the plurality of dies 104. In the example embodiment, in particular, the X-direction size of the irradiation-target region 106 may be larger than the X-direction size of the planar shape of each of the plurality of dies 104 and may be twice as large as the X-direction size of the planar shape or larger. The Y-direction size of the irradiation-target region 106 may be larger than the Y-direction size of the planar shape of each of the plurality of dies 104 and may be twice as large as the Y-direction size of the planar shape or larger. In the example shown in FIG. 6 and FIG. 7, the irradiation-target region 106 includes eight dies 104 arranged in two rows by four columns. In this example, the plurality of initial MR elements included in the eight dies 104 are irradiated with a laser beam at the same time.

As shown in FIG. 7 and FIG. 8, the plurality of arrays 105 are arranged so that a plurality of the arrays 105 are aligned in each of the X and Y directions. In the example embodiment, in particular, the area of the planar shape of each of the plurality of arrays 105 may be smaller than the area of the planar shape of each of the plurality of dies 104. Each of the plurality of dies 104 includes four arrays 105 arranged in two rows by two columns, as the some arrays 105. The four arrays 105 are electrically connected to configure a bridge circuit.

The directions of the magnetization of the magnetization pinned layers 52 of the MR elements 50 are defined for each of the plurality of arrays 105. In the example embodiment, in particular, the plurality of arrays 105 include a plurality of first arrays 105A having magnetization of the magnetization pinned layers 52 whose directions are defined in the first magnetization direction (X direction) and a plurality of second arrays 105B having magnetization of the magnetization pinned layers 52 whose directions are defined in the second magnetization direction (−X direction). The plurality of first arrays 105A and the plurality of second arrays 105B are arranged so that the first arrays 105A and the second arrays 105B are aligned alternately in each of the plurality of dies 104 or across a plurality of dies 104.

Each of the plurality of dies 104 includes two first arrays 105A and two second arrays 105B. In each of the plurality of dies 104, the two first arrays 105A and the two second arrays 105B may be arranged in the same positional relationship. The two first arrays 105A form resistor sections R1 and R3. The two second arrays 105B form resistor sections R2 and R4. The two first arrays 105A and the two second arrays 105B are electrically connected so as to configure the bridge circuit shown in FIG. 1 and formed by the four resistor sections R1 to R4.

Element formation S13 includes forming a plurality of initial arrays to later become the plurality of arrays 105. In the fixation of element formation S13, some initial arrays of the plurality of initial arrays may be irradiated with laser light at the same time. By the plurality of MR elements 50, the plurality of lower electrodes 61, and the plurality of upper electrodes 62 being formed, the plurality of arrays 105 are completed.

In FIG. 7 and FIG. 8, the plurality of circles represent the plurality of respective MR elements 50. Note that, in FIG. 7 and FIG. 8, the plurality of MR elements 50 are illustrated larger than actual for convenience. The plurality of MR elements 50 are arranged so that a plurality of MR elements 50 are aligned in each of the X and Y directions. By assuming that m and n are each an integer larger than 1, each of the plurality of arrays 105 may include a plurality of the MR elements 50 arranged in m rows by n columns as the some MR elements 50. In the example shown in FIG. 7 and FIG. 8, each of the plurality of arrays 105 includes 16 MR elements 50 arranged in four rows by four columns. In each of the plurality of arrays 105, 16 MR elements 50 are electrically connected so as to configure any of the resistor sections R1 to R4.

Although not shown, each of the plurality of dies 104 further includes a plurality of electrode pads.

In FIG. 8, an arrow denoted by sign P1 schematically shows the size of a first pitch, which is an arrangement pitch (arrangement interval) of the plurality of dies 104. The first pitch P1 may be, for example, the interval between the barycenters of the planar shapes of two adjacent dies 104.

Note that, in FIG. 8, the arrangement pitch of two dies 104 adjacent in the X direction is shown as the first pitch P1. Although not shown, the arrangement pitch of two dies 104 adjacent in the Y direction, i.e., the first P1 in the Y direction, may be equal to or need not be equal to the first pitch P1 in the X direction shown in FIG. 8. In the following description, the first pitch P1 is assumed to be equal in the X direction and the Y direction unless otherwise specified.

In FIG. 8, an arrow denoted by sign P2 schematically shows the size of a second pitch, which is an arrangement pitch (arrangement interval) of the plurality of arrays 105 in each of the plurality of dies 104. The second pitch P2 may be, for example, the interval between the barycenters of the planar shapes of two adjacent arrays 105.

Note that, in FIG. 8, the arrangement pitch of two arrays 105 adjacent in the Y direction is shown as the second pitch P2. The arrangement pitch of two arrays 105 adjacent in the X direction, i.e., the second P2 in the X direction, may be equal to or need not be equal to the second pitch P2 in the Y direction shown in FIG. 8. In the following description, the second pitch P2 is assumed to be equal in the X direction and the Y direction unless otherwise specified.

The arrangement pitch of two adjacent arrays 105 included in different dies 104 may be equal to or need not be equal to the second pitch P2. In the former case, the plurality of arrays 105 may be arranged at equal intervals irrespective of the plurality of dies 104.

In FIG. 8, an arrow denoted by sign P3 schematically shows the size of a third pitch, which is an arrangement pitch (arrangement interval) of the plurality of MR elements 50 in each of the plurality of arrays 105. The third pitch P3 may be, for example, the interval between the barycenters of the planar shapes of two adjacent MR elements 50.

Note that, in FIG. 8, the arrangement pitch of two MR elements 50 adjacent in the X direction is shown as the third pitch P3. The arrangement pitch of two MR elements 50 adjacent in the Y direction, i.e., the third P3 in the Y direction, may be equal to, or need not be equal to the third pitch P3 in the X direction shown in FIG. 8. In the following description, the third pitch P3 is assumed to be equal in the X direction and the Y direction unless otherwise specified.

The arrangement pitch of two adjacent MR elements 50 included in different arrays 105 may be equal to or need not be equal to the third pitch P3. The arrangement pitch of two adjacent MR elements 50 included in different dies 104 may be equal to or need not be equal to the third pitch P3.

Next, a relationship of the first pitch P1, the second pitch P2, and the third pitch P3 will be described. In the wafer 100, the plurality of dies 104 and the plurality of arrays 105 of each of the plurality of dies 104 are arranged in a manner that the second pitch P2 is not larger than the first pitch P1. In the example embodiment, in particular, the plurality of dies 104 and the plurality of arrays 105 of each of the plurality of dies 104 are arranged in a manner that the first pitch P1 is larger than the second pitch P2, i.e., P1 > P2 is satisfied.

In the wafer 100, the plurality of arrays 105 of each of the plurality of dies 104 and the MR elements 50 of each of the plurality of arrays 105 are arranged in a manner that the third pitch P3 is not larger than the second pitch P2. In the example embodiment, in particular, the plurality of arrays 105 of each of the plurality of dies 104 and the plurality of MR elements 50 of each of the plurality of arrays 105 are arranged in a manner that the second pitch P2 is larger than the third pitch P3, i.e., P2 > P3 is satisfied.

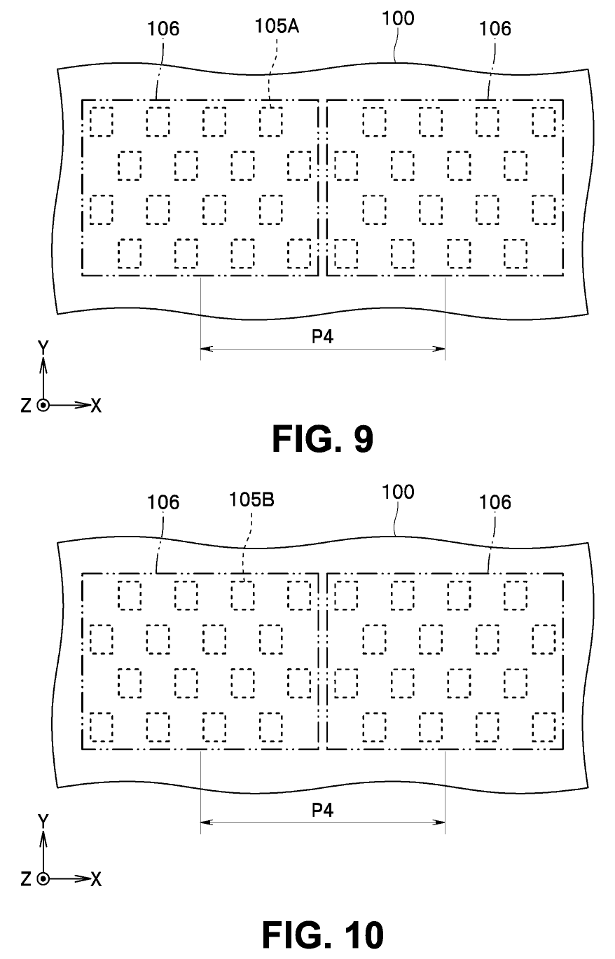

Next, the irradiation-target regions 106 in each of the first fixation and the second fixation of the fixation of element formation S13 will be described with reference to FIG. 9 and FIG. 10. FIG. 9 is an explanatory view showing the irradiation-target regions 106 in the first fixation. FIG. 10 is an explanatory diagram showing the irradiation-target regions 106 in the second fixation. In the fixation, irradiation of laser light is performed while moving the wafer 100 in a specific direction (for example, the X direction or the −X direction). FIG. 9 and FIG. 10 show two irradiation-target regions 106 adjacent in the X direction. Note that FIG. 9 and FIG. 10 show an example where the two irradiation-target regions 106 do not overlap each other. However, the two irradiation-target regions 106 possibly overlap each other depending on the pulse width of laser light and the moving speed of the wafer 100.

FIG. 9 shows a plurality of first initial arrays irradiated with laser light in the first fixation among the plurality of initial arrays to later become the plurality of arrays 105. The plurality of first initial arrays later become the plurality of first arrays 105A. In FIG. 9, the reference sign 105A is attached to each of the plurality of first initial arrays for convenience. In the first fixation, a first mask not shown is used to selectively irradiate the plurality of first initial arrays of the plurality of dies 104 with laser light. The first mask has the function of blocking laser light with which a plurality of second initial arrays to be described later are irradiated.

FIG. 10 shows the plurality of second initial arrays irradiated with laser light in the second fixation among the plurality of initial arrays to later become the plurality of arrays 105. The plurality of second initial arrays later become the plurality of second arrays 105B. In FIG. 10, the reference sign 105B is attached to each of the plurality of second initial arrays for convenience. In the second fixation, a second mask not shown is used to selectively irradiate the plurality of second initial arrays of the plurality of dies 104 with laser light. The second mask has the function of blocking laser light with which a plurality of first initial arrays are irradiated.

Here, as shown in FIG. 9 and FIG. 10, when the wafer 100 is moved in the specific direction (for example, the X direction or the −X direction) in each of the first fixation and second fixation, the pitch of two irradiation-target regions 106 adjacent at the minimum interval in this specific direction and not overlapping each other is referred to as a fourth pitch P4. The fourth pitch P4 may be, for example, the interval between the barycenters of the two irradiation-target regions 106. In the example embodiment, the fourth pitch P4 is larger than the first pitch P1.

Next, operation and effects of the magnetic sensor 1 according to the example embodiment will be described. In the example embodiment, the plurality of dies 104 and the plurality of arrays 105 of each of the plurality of dies 104 are arranged in a manner that the second pitch P2 is not larger than the first pitch P1. The plurality of arrays 105 of each of the plurality of dies 104 and the MR elements 50 of each of the plurality of arrays 105 are arranged in a manner that the third pitch P3 is not larger than the second pitch P2. With this, according to the example embodiment, a large number of initial MR elements can be irradiated with laser light at the same time compared to a case where a plurality of initial MR elements are arranged so as not to satisfy the above requirement. In other words, according to the example embodiment, the directions of the magnetization of the magnetization pinned layers 52 can be fixed efficiently.

According to the example embodiment, the directions of the magnetization of the magnetization pinned layers 52 can be fixed efficiently, which exerts the following effects. First, since the time required for the fixation can be reduced, the lead time of the magnetic sensor 1 can be reduced, which can reduce the manufacturing cost of the magnetic sensor 1. Since the time required for the fixation can be reduced, fluctuations in environment in the fixation can be suppressed, which can consequently suppress variations in quality of the magnetic sensor 1. The number of oscillation times of a laser oscillator that generates laser light can be reduced, which can consequently increase the life cycle of the laser oscillator and the like and also reduce the number of replacement times of parts such as a lens and a mirror. The pulse repetition frequency of laser light can be low, which can consequently stabilize laser light and suppress variations in quality of the magnetic sensor 1.

In the example embodiment, the area of the planar shape of each of the plurality of dies 104 may be larger than the area of the planar shape of each of the plurality of arrays 105, and the area of each of the irradiation-target regions 106 may be larger than the area of the planar shape of each of the plurality of dies 104. With this, according to the example embodiment, a larger number of initial MR elements can be irradiated with laser light at the same time.

In the example embodiment, in each of the plurality of dies 104, the two first arrays 105A and the two second arrays 105B are arranged in the same positional relationship. With this, according to the example embodiment, the fixation can be performed in the same condition for each of the plurality of dies 104, which can fix the directions of the magnetization of the magnetization pinned layers 52 efficiently.

According to the example embodiment, by the arrangement pitch of two adjacent arrays 105 included in different dies 104 being equal to the second pitch P2, the fixation can be performed in the same condition irrespective of arrangement of the plurality of arrays 105, which can fix the directions of the magnetization of the magnetization pinned layers 52 efficiently.

### Second Example Embodiment

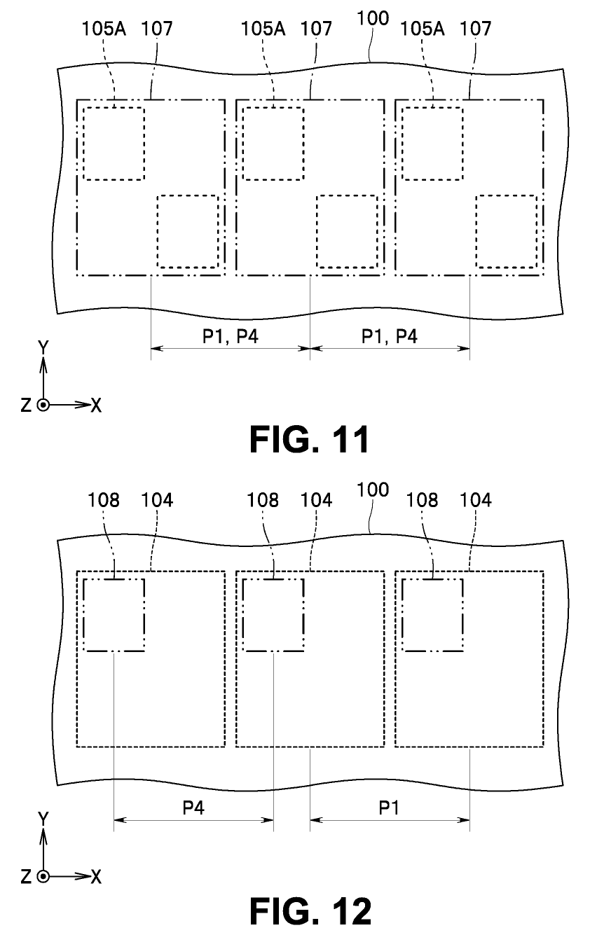

Next, a second example embodiment of the disclosure will be described with reference to FIG. 11. FIG. 11 is an explanatory diagram showing irradiation-target regions in the example embodiment.

In the example embodiment, in the fixation of element formation S13, the relative area of each of irradiation-target regions 107, which is a region of the stack including the plurality of initial MR elements irradiated with laser light at the same time, is different from the area of each of the irradiation-target region 106 in the first example embodiment. In other words, in the example embodiment, the area of the irradiation-target region 107 is the same as or approximately the same as the area of the planar shape of each of the plurality of dies 104. In the example embodiment, in particular, the X-direction size of the irradiation-target region 107 is the same as or approximately the same as the X-direction size of the planar shape of each of the plurality of dies 104. The Y-direction size of the irradiation-target region 107 is the same as or approximately the same as the Y-direction size of the planar shape of each of the plurality of dies 104.

Note that the area of the planar shape of each of the plurality of dies 104 may be the same as or different from that in the first example embodiment. Hence, the area of the irradiation-target region 107 may be smaller than the area of the irradiation-target region 106, may be the same as the area of the irradiation-target region 106, or may be larger than the area of the irradiation-target region 106.

When the X-direction size of the irradiation-target region 107 is the same as or approximately the same as the X-direction size of the planar shape of each of the plurality of dies 104, the Y-direction size of the irradiation-target region 107 may be larger than the Y-direction size of the planar shape of each of the plurality of dies 104. When the Y-direction size of the irradiation-target region 107 is the same as or approximately the same as the Y-direction size of the planar shape of each of the plurality of dies 104, the X-direction size of the irradiation-target region 107 may be larger than the X-direction size of the planar shape of each of the plurality of dies 104.

FIG. 11 shows a plurality of first initial arrays irradiated with laser light in the first fixation of the fixation among the plurality of initial arrays to later become the plurality of arrays 105. The plurality of first initial arrays later become the plurality of first arrays 105A. In FIG. 11, the reference sign 105A is attached to each of the plurality of first initial arrays. In the first fixation, a first mask not shown may be used to selectively irradiate two first initial arrays with laser light. The two first initial arrays may be included in one die 104 or may be included in two respective adjacent dies 104. The first mask has the function of blocking laser light with which a plurality of second initial arrays are irradiated.

As described in the first example embodiment, the plurality of second initial arrays are initial arrays irradiated with laser light in the second fixation of the fixation among the plurality of initial arrays to later become the plurality of arrays 105. The plurality of second initial arrays later become the plurality of second arrays 105B. Although not shown, in the second fixation, a second mask not shown may be used to selectively irradiate two second initial arrays with laser light. The two second initial arrays may be included in one die 104 or may be included in two respective adjacent dies 104. The second mask has the function of blocking laser light with which a plurality of first initial arrays are irradiated.

Here, similarly to the first example embodiment, when the wafer 100 is moved in a specific direction (for example, the X direction or the −X direction) in each of the first fixation and second fixation, the pitch of two irradiation-target regions 107 adjacent at the minimum interval in this specific direction and not overlapping each other is referred to as a fourth pitch P4. The fourth pitch P4 may be, for example, the interval between the barycenters of the two irradiation-target regions 107. In the example embodiment, the fourth pitch P4 is equal to or approximately equal to the first pitch P1, which is the arrangement pitch (arrangement interval) of the plurality of dies 104.

The configuration, operations, and effects of the example embodiment are otherwise the same as those of the first example embodiment.

### Third Example Embodiment

Next, a third example embodiment of the disclosure will be described with reference to FIG. 12. FIG. 12 is an explanatory diagram showing irradiation-target regions in the example embodiment.

In the example embodiment, in the fixation of element formation S13, the relative area of each of irradiation-target regions 108, which is a region of the stack including the plurality of initial MR elements irradiated with laser light at the same time, is different from the area of each of the irradiation-target region 106 in the first example embodiment. In other words, in the example embodiment, the area of the irradiation-target region 108 may be smaller than the area of the planar shape of each of the plurality of dies 104 and is the same as or approximately the same as the area of the planar shape of each of the plurality of arrays 105. In the example embodiment, in particular, the X-direction size of the irradiation-target region 108 is the same as or approximately the same as the X-direction size of the planar shape of each of the plurality of arrays 105. The Y-direction size of the irradiation-target region 108 is the same as or approximately the same as the Y-direction size of the planar shape of each of the plurality of arrays 105.

Note that the area of the planar shape of each of the plurality of arrays 105 may be the same as or different from that in the first example embodiment. Hence, the area of the irradiation-target region 108 may be smaller than the area of the irradiation-target region 106, may be the same as the area of the irradiation-target region 106, or may be larger than the area of the irradiation-target region 106.

In the example embodiment, the first fixation of the fixation includes a first sub-step of fixing the direction of the magnetization of the initial magnetization pinned layer of each of the plurality of initial MR elements of one first initial array of the two first initial arrays included in each of the plurality of dies 104 and a second sub-step of fixing the direction of the magnetization of the initial magnetization pinned layer of each of the plurality of initial MR elements of the other first initial array of the two first initial arrays included in each of the plurality of dies 104. FIG. 12 shows the irradiation-target regions 108 in the first sub-step. In the first sub-step, the one first initial array is selectively irradiated with laser light. In the first sub-step, a mask having the function of blocking laser light with which a plurality of second initial arrays adjacent to the one first initial array are irradiated may be used.

Similarly, in the second sub-step, the other first initial array is selectively irradiated with laser light. In the second sub-step, a mask having the function of blocking laser light with which a plurality of second initial arrays adjacent to the other first initial array are irradiated may be used.

In the example embodiment, the second step of the fixation includes a third sub-step of fixing the direction of the magnetization of the initial magnetization pinned layer of each of the plurality of initial MR elements of one second initial array of the two second initial arrays included in each of the plurality of dies 104 and a fourth sub-step of fixing the direction of the magnetization of the initial magnetization pinned layer of each of the plurality of initial MR elements of the other second initial array of the two second initial arrays included in each of the plurality of dies 104. In the third sub-step, the one second initial array is selectively irradiated with laser light. In the third sub-step, a mask having the function of blocking laser light with which a plurality of first initial arrays adjacent to the one second initial array are irradiated may be used.

Similarly, in the fourth sub-step, the other second initial array is selectively irradiated with laser light. In the fourth sub-step, a mask having the function of blocking laser light with which a plurality of first initial arrays adjacent to the other second initial array are irradiated may be used.

Here, similarly to the first example embodiment, when the wafer 100 is moved in a specific direction (for example, the X direction or the −X direction) in each of the first to fourth sub-steps, the pitch of two irradiation-target regions 108 adjacent at the minimum interval in this specific direction and not overlapping each other is referred to as a fourth pitch P4. The fourth pitch P4 may be, for example, the interval between the barycenters of the two irradiation-target regions 108. In the example embodiment, the fourth pitch P4 is equal to or approximately equal to the first pitch P1, which is the arrangement pitch (arrangement interval) of the plurality of dies 104.

The configuration, operations, and effects of the example embodiment are otherwise the same as those of the first example embodiment.

### Fourth Example Embodiment

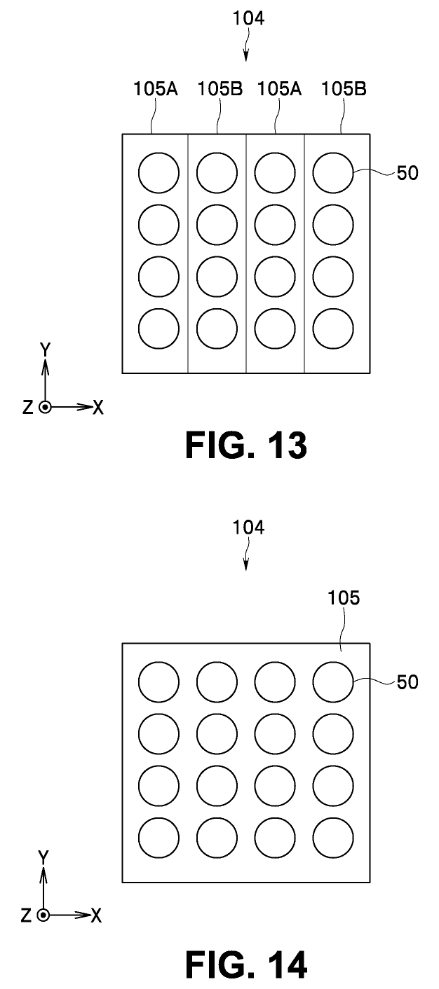

Next, a fourth example embodiment of the disclosure will be described with reference to FIG. 13. FIG. 13 is a plan view showing one die 104 in the example embodiment.

In the example embodiment, the arrangement of the plurality of MR elements 50 in each of the plurality of arrays 105 is different from that in the first example embodiment. In the example embodiment, in each of the plurality of arrays 105, the plurality of MR elements 50 are arranged so that different numbers of MR elements 50 are aligned in each of the X and Y directions. In the example shown in FIG. 13, the plurality of MR elements 50 are arranged so that one MR element 50 is arranged in the X direction and four MR elements 50 are aligned in the Y direction in each of the plurality of arrays 105. In other words, in the example shown in FIG. 13, each of the plurality of arrays 105 includes four MR elements 50 arranged in four rows by one column.

In the example embodiment, in each of the plurality of dies 104, four arrays 105 are aligned in the X direction. In other words, each of the plurality of dies 104 includes four arrays 105 arranged in one row by four columns. Note that, similarly to the first example embodiment, the plurality of first arrays 105A and the plurality of second arrays 105B are arranged so that the first arrays 105A and the second arrays 105B are aligned alternately in each of the plurality of dies 104 or across a plurality of dies 104.

The arrangement pitch of two arrays 105 adjacent in the X direction, i.e., the second pitch in the X direction, is smaller than the second pitch in the Y direction and equal to the arrangement pitch of two MR elements 50 adjacent in the X direction. In the example embodiment, the arrangement pitch of two adjacent MR elements 50 included in different arrays 105 is referred to as a third pitch in the X direction for convenience. The second pitch in the X direction is equal to the third pitch in the X direction.

In the fixation of element formation S13, the area of an irradiation-target region, which is a region of a stack including the plurality of initial MR elements irradiated with laser light at the same time, may be larger than the area of the planar shape of each of the plurality of dies 104 similarly to the first example embodiment. Alternatively, the area of the irradiation-target region may be the same as or approximately the same as the area of the planar shape of each of the plurality of dies 104 similarly to the second example embodiment. Alternatively, the area of the irradiation-target region may be the same as or approximately the same as the area of the planar shape of each of the plurality of arrays 105 similarly to the third example embodiment.

The configuration, operations, and effects of the example embodiment are otherwise the same as those of any of the first to third example embodiments.

### Fifth Example Embodiment

Next, a fifth example embodiment of the disclosure will be described with reference to FIG. 14. FIG. 14 is a plan view showing one die 104 in the example embodiment.

In the example embodiment, each of the plurality of dies 104 includes one array 105. The arrangement pitch of two dies 104 adjacent in the X direction is equal to or approximately equal to the arrangement pitch of two arrays 105 adjacent in the X direction. The arrangement pitch of two dies 104 adjacent in the Y direction is equal to or approximately equal to the arrangement pitch of two arrays 105 adjacent in the Y direction.

In the fixation of element formation S13, the area of an irradiation-target region, which is a region of a stack including the plurality of initial MR elements irradiated with laser light at the same time, may be larger than the area of the planar shape of each of the plurality of dies 104 similarly to the first example embodiment. Alternatively, the area of the irradiation-target region may be the same as or approximately the same as the area of the planar shape of each of the plurality of dies 104 similarly to the second example embodiment. In this case, similarly to the third example embodiment, the area of the irradiation-target region is the same as or approximately the same as the area of the planar shape of each of the plurality of arrays 105.

The configuration, operations, and effects of the example embodiment are otherwise the same as those of any of the first to third example embodiments.

### Sixth Example Embodiment

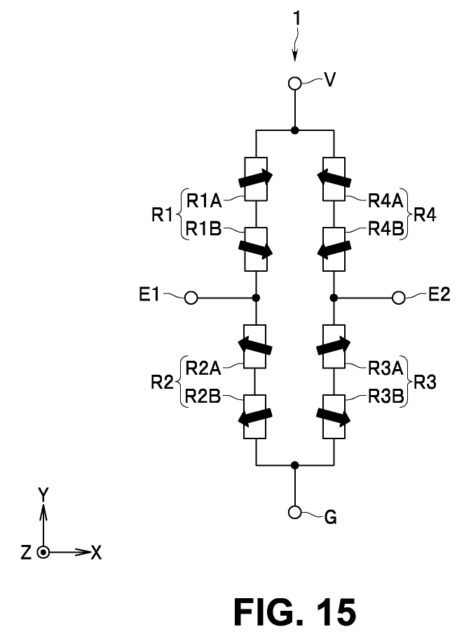

Next, a sixth example embodiment of the disclosure will be described. First, a circuit configuration of the magnetic sensor 1 according to the example embodiment will be described with reference to FIG. 15. FIG. 15 is a circuit diagram showing a circuit configuration of the magnetic sensor 1.

In the example embodiment, the resistor section R1 includes two parts R1A and R1B connected in series in this order from the power supply port V side. The resistor section R2 includes two parts R2A and R2B connected in series in this order from the output port E1 side. The resistor section R3 includes two parts R3A and R3B connected in series in this order from the output port E2 side. The resistor section R4 includes two parts R4A and R4B connected in series in this order from the power supply port V side.

Each of the parts R1A, R1B, R2A, R2B, R3A, R3B, R4A, and R4B includes two or more MR elements 50, which are some MR elements 50 of the plurality of MR elements 50.

In FIG. 15, each of a plurality of arrows illustrated to overlap the respective parts R1A, R1B, R2A, R2B, R3A, R3B, R4A, and R4B indicate the direction of the magnetization of the magnetization pinned layer 52 of each of the plurality of MR elements 50 in the part. The direction of the magnetization of each of the magnetization pinned layers 52 in the part R1A and the direction of the magnetization of each of the magnetization pinned layers 52 in the part R1B form a specific relative angle except for 0˚ and 180˚.

The intermediate direction of the direction of the magnetization of each of the magnetization pinned layers 52 in the part R1A and the direction of each of the magnetization of the magnetization pinned layers 52 in the part R1B correspond to the first magnetization direction. In the example embodiment, the directions of the magnetization of all the magnetization pinned layers 52 included in the part R1A are the same. The directions of the magnetization of all the magnetization pinned layers 52 included in the part R1B are the same. When the number of MR elements 50 included in the part R1A and the number of MR elements 50 included in the part R1B are the same, the direction obtained by averaging the directions of the magnetization of all the magnetization pinned layers 52 included in the parts R1A and R1B is the first magnetization direction.

Similarly, the direction of the magnetization of each of the magnetization pinned layers 52 in the part R3A and the direction of the magnetization of each of the magnetization pinned layers 52 in the part R3B form a specific relative angle except for 0˚ and 180˚. The intermediate direction of the direction of the magnetization of each of the magnetization pinned layers 52 in the part R3A and the direction of the magnetization of each of the magnetization pinned layers 52 in the part R3B correspond to the first magnetization direction. The direction obtained by averaging the directions of the magnetization of all the magnetization pinned layers 52 included in the parts R3A and R3B is the first magnetization direction.

In the example shown in FIG. 15, the first magnetization direction is the X direction. The magnetization of the magnetization pinned layers 52 in each of the parts R1A and R3A includes a component in a magnetization direction obtained by rotating from the X direction toward the Y direction by α˚. The magnetization of the magnetization pinned layers 52 in each of the parts R1B and R3B includes a component in a magnetization direction obtained by rotating from the X direction toward the −Y direction by α˚. Note that α is larger than 0 and smaller than 90.

Similarly, the direction of the magnetization of each of the magnetization pinned layers 52 in the part R2A and the direction of the magnetization of each of the magnetization pinned layers 52 in the part R2B form a specific relative angle except for 0˚ and 180˚. The intermediate direction of the direction of the magnetization of each of the magnetization pinned layers 52 in the part R2A and the direction of the magnetization of each of the magnetization pinned layers 52 in the part R2B correspond to the second magnetization direction. The direction obtained by averaging the directions of the magnetization of all the magnetization pinned layers 52 included in the parts R2A and R2B is the second magnetization direction.

Similarly, the direction of the magnetization of each of the magnetization pinned layers 52 in the part R4A and the direction of the magnetization of each of the magnetization pinned layers 52 in the part R4B form a specific relative angle except for 0˚ and 180˚. The intermediate direction of the direction of the magnetization of each of the magnetization pinned layers 52 in the part R4A and the direction of the magnetization of each of the magnetization pinned layers 52 in the part R4B correspond to the second magnetization direction. The direction obtained by averaging the directions of the magnetization of all the magnetization pinned layers 52 included in the parts R4A and R4B is the second magnetization direction.

In the example shown in FIG. 15, the second magnetization direction is the −X direction. The magnetization of the magnetization pinned layer 52 of each of the plurality of MR elements 50 in the parts R2A and R4A includes a component in a magnetization direction obtained by rotating from the −X direction toward the Y direction by β˚. The magnetization of the magnetization pinned layer 52 of each of the plurality of MR elements 50 in the parts R2B and R4B includes a component in a magnetization direction obtained by rotating from the −X direction toward the −Y direction by β˚. Note that β is larger than 0 and smaller than 90. β may be equal to α or different from α.

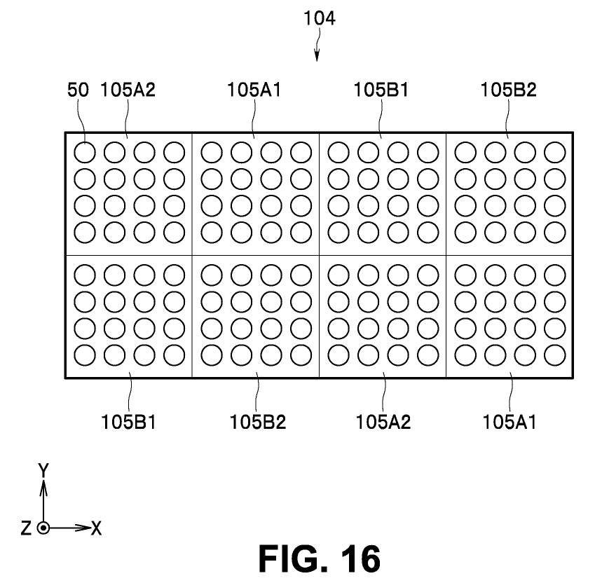

Next, a configuration of each of the plurality of dies 104 according to the example embodiment will be described with reference to FIG. 16. FIG. 16 is a plan view showing one die 104 in the example embodiment. In the example embodiment, each of the plurality of dies 104 includes two arrays 105A1, two arrays 105A2, two arrays 105B1, and two arrays 105B2 as the plurality of arrays 105. In the example shown in FIG. 16, the arrays 105A2, 105A1, 105B1, and 105B2 are aligned in the X direction in this order at a Y-direction-side position of the die 104, and the arrays 105B1, 105B2, 105A2, and 105A1 are aligned in the X direction in this order at a −Y-direction-side position of the die 104.

In the two arrays 105A1, the directions of the magnetization of the magnetization pinned layers 52 are defined in a magnetization direction obtained by rotating from the X direction toward the Y direction by α˚. In the two arrays 105A2, the directions of the magnetization of the magnetization pinned layers 52 are defined in a magnetization direction obtained by rotating from the X direction toward the −Y direction by α˚. In the two arrays 105B1, the directions of the magnetization of the magnetization pinned layers 52 are defined in a magnetization direction obtained by rotating from the −X direction toward the Y direction by β˚. In the two arrays 105B2, the directions of the magnetization of the magnetization pinned layers 52 are defined in a magnetization direction obtained by rotating from the −X direction toward the −Y direction by β˚.

Note that the arrangement of the arrays 105A1, 105A2, 105B1, and 105B2 is not limited to the example shown in FIG. 16 and may be any.

The two arrays 105A1 form the part R1A of the resistor section R1 and the part R3A of the resistor section R3. The two arrays 105A2 form the part R1B of the resistor section R1 and the part R3B of the resistor section R3. The two arrays 105B1 form the part R2A of the resistor section R2 and the part R4A of the resistor section R4. The two arrays 105B2 form the part R2B of the resistor section R2 and the part R4B of the resistor section R4.

One of the two arrays 105A1 and one of the two arrays 105A2 are electrically connected to configure the resistor section R1. One of the two arrays 105B1 and one of the two arrays 105B2 are electrically connected to configure the resistor section R2. The other one of the two arrays 105A1 and the other one of the two arrays 105A2 are electrically connected to configure the resistor section R3. The other one of the two arrays 105B1 and the other one of the two arrays 105B2 are electrically connected to configure the resistor section R4. The arrays 105A1, 105A2, 105B1, and 105B2 are electrically connected so as to configure the bridge circuit shown in FIG. 15 and formed by the four resistor sections R1 to R4.

The configuration, operations, and effects of the example embodiment are otherwise the same as those of the first example embodiment.

### Seventh Example Embodiment

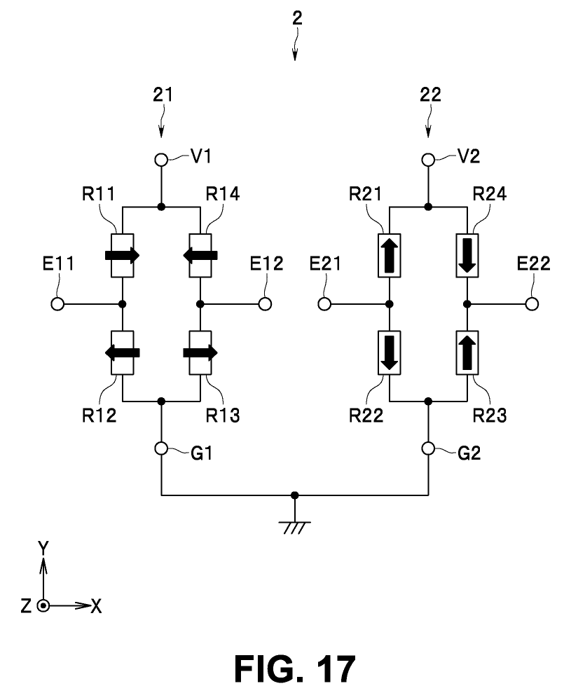

Next, a seventh example embodiment of the disclosure will be described. First, a circuit configuration of a magnetic sensor 2 according to the example embodiment will be described with reference to FIG. 17. FIG. 17 is a circuit diagram showing a circuit configuration of the magnetic sensor 2.

The magnetic sensor 2 includes a first detection circuit 21, which is a bridge circuit, and a second detection circuit 22, which is a bridge circuit. The configuration of the first detection circuit 21 is similar to the configuration of the magnetic sensor 1 according to the first example embodiment. Specifically, the first detection circuit 21 includes a power supply port V1, a ground port G1, two output ports E11 and E12, and four resistor sections R11, R12, R13, and R14. A voltage or an electric current having a specific magnitude is applied to the power supply port V1. The ground port G1 is connected to the ground.

The resistor section R11 is provided between the power supply port V1 and the output port E11 in the circuit configuration. The resistor section R12 is provided between the ground port G1 and the output port E11 in the circuit configuration. The resistor section R13 is provided between the ground port G1 and the output port E12 in the circuit configuration. The resistor section R14 is provided between the power supply port V1 and the output port E12 in the circuit configuration.

The configuration of the second detection circuit 22 is similar to the configuration of the first detection circuit 21. Specifically, the second detection circuit 22 includes a power supply port V2, a ground port G2, two output ports E21 and E22, and four resistor sections R21, R22, R23, and R24. A voltage or an electric current having a specific magnitude is applied to the power supply port V2. The ground port G2 is connected to the ground.

The resistor section R21 is provided between the power supply port V2 and the output port E21 in the circuit configuration. The resistor section R22 is provided between the ground port G2 and the output port E21 in the circuit configuration. The resistor section R23 is provided between the ground port G2 and the output port E22 in the circuit configuration. The resistor section R24 is provided between the power supply port V2 and the output port E22 in the circuit configuration.

Each of the resistor sections R11 to R14 and R21 to R24 includes two or more MR elements 50, which are some MR elements 50 of the plurality of MR elements 50.

The magnetization of the magnetization pinned layer 52 of each of the plurality of MR elements 50 in the resistor sections R11 and R13 contains a component in a first magnetization direction. The magnetization of the magnetization pinned layer 52 of each of the plurality of MR elements 50 in the resistor sections R12 and R14 contains a component in a second magnetization direction opposite to the first magnetization direction. In FIG. 17, the plurality of arrows that are illustrated to overlap the resistor sections R11 and R13 represent the first magnetization direction, and the plurality of arrows illustrated to overlap the resistor sections R12 and R14 represent the second magnetization direction. In the example shown in FIG. 17, the first magnetization direction is the X direction, and the second magnetization direction is the −X direction.

The magnetization of the magnetization pinned layer 52 of each of the plurality of MR elements 50 in the resistor sections R21 and R23 contains a component in a third magnetization direction. The magnetization of the magnetization pinned layer 52 of each of the plurality of MR elements 50 in the resistor sections R22 and R24 contains a component in a fourth magnetization direction opposite to the third magnetization direction. In FIG. 17, the plurality of arrows that are illustrated to overlap the resistor sections R21 and R23 represent the third magnetization direction, and the plurality of arrows illustrated to overlap the resistor sections R22 and R24 represent the fourth magnetization direction. In the example shown in FIG. 17, the third magnetization direction is the Y direction, and the fourth magnetization direction is the −Y direction.

The magnetic sensor 2 may generate, as a first detection signal, a signal corresponding to the potential difference between the output ports E11 and E12, and generates, as a second detection signal, a signal corresponding to the potential difference between the output ports E21 and E22. The first detection signal may have a correspondence with a component in a direction parallel to the X direction of a detection-target magnetic field. The second detection signal may have a correspondence with a component in a direction parallel to the Y direction of the detection-target magnetic field.

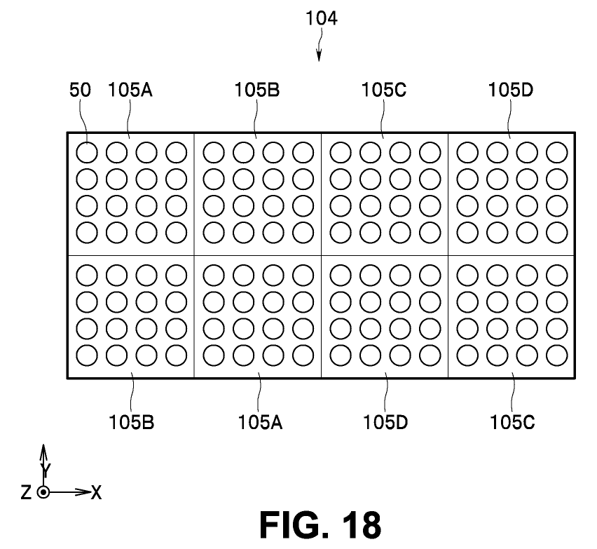

Next, a configuration of each of the plurality of dies 104 according to the example embodiment will be described with reference to FIG. 18. FIG. 18 is a plan view showing one die 104 in the example embodiment. In the example embodiment, each of the plurality of dies 104 includes two arrays 105A, two arrays 105B, two arrays 105C, and two arrays 105D as the plurality of arrays 105. In the example shown in FIG. 18, the arrays 105A, 105B, 105C, and 105D are aligned in the X direction in this order at a Y-direction-side position of the die 104, and the arrays 105B, 105A, 105D, and 105C are aligned in the X direction in this order at a −Y-direction-side position of the die 104.

In the two arrays 105A, the directions of the magnetization of the magnetization pinned layers 52 are defined in a first magnetization direction (X direction). In the two arrays 105B, the directions of the magnetization of the magnetization pinned layers 52 are defined in a second magnetization direction (−X direction). In the two arrays 105C, the directions of the magnetization of the magnetization pinned layers 52 are defined in a third magnetization direction (Y direction). In the two arrays 105D, the directions of the magnetization of the magnetization pinned layers 52 are defined in a fourth magnetization direction (−Y direction).

Note that the arrangement of the arrays 105A to 105D is not limited to the example shown in FIG. 18 and may be any.

The two arrays 105A form the resistor sections R11 and R13. The two arrays 105B form the resistor sections R12 and R14. The two arrays 105A and the two arrays 105B are electrically connected so as to configure the first detection circuit 21 shown in FIG. 17.

The two arrays 105C form the resistor sections R21 and R23. The two arrays 105D form the resistor sections R22 and R24. The two arrays 105C and the two arrays 105D are electrically connected so as to configure the second detection circuit 22 shown in FIG. 17.

Note that the example embodiment can be combined with any of the first to sixth example embodiments. The configuration, operations, and effects of the example embodiment are otherwise the same as those of any of the first to sixth example embodiments.

Note that the disclosure is not limited to each of the foregoing example embodiments, and various modifications may be made thereto. For example, the arrangement of the plurality of MR elements 50 and the arrangement of the plurality of arrays 105 are not limited to the example embodiments described but may be freely set as long as the requirements set forth in the claims are satisfied. In each of the plurality of dies 104, the plurality of arrays 105 may be aligned in a row in the Y direction.

Each of the plurality of dies 104 may include at least one first array having magnetization of each of the magnetization pinned layers 52 whose direction is the X direction, at least one second array having magnetization of each of the magnetization pinned layers 52 whose direction is the −X direction, at least one third array having magnetization of each of the magnetization pinned layers 52 whose direction is the Y direction, and at least one fourth array having magnetization of each of the magnetization pinned layers 52 whose direction is the −Y direction.

The plurality of MR elements 50 may be arranged on an inclined surface inclined with respect to a reference plane (surface parallel to a surface of the wafer). In this case, the direction of magnetization of each of the magnetization pinned layers 52 may be defined as a direction inclined with respect to the reference plane. In the fixation of fixing the directions of the magnetization of the initial magnetization pinned layers to later become the magnetization pinned layers 52, an external magnetic field in a direction parallel to the reference plane may be used as an external magnetic field applied to the initial magnetization pinned layer.

As described above, a wafer according to one embodiment of the disclosure is used for manufacturing of a plurality of magnetic sensors. A wafer of the disclosure includes: a plurality of magnetoresistive elements arranged regularly; a plurality of arrays each including some magnetoresistive elements of the plurality of magnetoresistive elements and also arranged regularly; and a plurality of dies sectioned regularly to correspond to the plurality of respective magnetic sensors and also each including some arrays of the plurality of arrays. Each of the plurality of magnetoresistive elements includes a magnetization pinned layer having magnetization whose direction is fixed, a free layer having magnetization whose direction is variable according to an applied magnetic field, and a gap layer arranged between the magnetization pinned layer and the free layer. The directions of the magnetization of the magnetization pinned layers are defined for each of the plurality of arrays. The plurality of dies are arranged at a first pitch. The some arrays are arranged at a second pitch in each of the plurality of dies and also electrically connected to configure a bridge circuit. The some magnetoresistive elements are arranged at a third pitch in each of the plurality of arrays and also electrically connected to each other. The plurality of dies and the some arrays are arranged in a manner that the second pitch is not larger than the first pitch. The some arrays and the some magnetoresistive elements are arranged in a manner that the third pitch is not larger than the second pitch.

In the wafer according to one embodiment of the disclosure, the some arrays and the some magnetoresistive elements may be arranged in a manner that the second pitch is larger than the third pitch. By assuming that m and n are each an integer larger than 1, the some magnetoresistive elements may be arranged in m rows by n columns in each of the plurality of arrays.

In the wafer according to one embodiment of the disclosure, the some arrays and the some magnetoresistive elements may be arranged in a manner that the second pitch is equal to the third pitch.

In the wafer according to one embodiment of the disclosure, the plurality of dies and the some arrays may be arranged in a manner that the first pitch is larger than the second pitch.

In the wafer according to one embodiment of the disclosure, the plurality of arrays may be arranged at equal intervals irrespective of the plurality of dies.

In the wafer according to one embodiment of the disclosure, the some arrays may be arranged in a same positional relationship for each of the plurality of dies.

A magnetic sensor manufacturing method according to one embodiment of the disclosure is a manufacturing method of manufacturing a plurality of magnetic sensors by using a wafer. The wafer includes: a plurality of magnetoresistive elements arranged regularly; a plurality of arrays each including some magnetoresistive elements of the plurality of magnetoresistive elements and also arranged regularly; and a plurality of dies sectioned regularly to correspond to the plurality of respective magnetic sensors and also each including some arrays of the plurality of arrays. Each of the plurality of magnetoresistive elements includes a magnetization pinned layer having magnetization whose direction is fixed, a free layer having magnetization whose direction is variable according to an applied magnetic field, and a gap layer arranged between the magnetization pinned layer and the free layer. The directions of the magnetization of the magnetization pinned layers are defined for each of the plurality of arrays. The plurality of dies are arranged at a first pitch. The some arrays are arranged at a second pitch in each of the plurality of dies and also electrically connected to configure a bridge circuit. The some magnetoresistive elements are arranged at a third pitch in each of the plurality of arrays and also electrically connected to each other. The plurality of dies and the some arrays are arranged in a manner that the second pitch is not larger than the first pitch. The some arrays and the some magnetoresistive elements are arranged in a manner that the third pitch is not larger than the second pitch.

The magnetic sensor manufacturing method according to one embodiment of the disclosure includes: producing the wafer; dicing the plurality of dies from the wafer to produce a plurality of chips; and producing the plurality of magnetic sensors from the plurality of chips. The producing of the wafer includes element formation of forming the plurality of magnetoresistive elements and the plurality of arrays and forming wiring for connecting the plurality of magnetoresistive elements. The element formation includes forming a plurality of initial magnetoresistive elements each including an initial magnetization pinned layer to later become the magnetization pinned layer and the free layer and fixation of fixing a direction of the magnetization of the initial magnetization pinned layer of each of the plurality of initial magnetoresistive elements.

In the magnetic sensor manufacturing method according to one embodiment of the disclosure, the fixation may fix the direction of the magnetization of the initial magnetization pinned layer by using laser light and an external magnetic field. The plurality of arrays may include a plurality of first arrays and a plurality of second arrays. The magnetization of the magnetization pinned layers in the plurality of first arrays may include a component in a first direction. The magnetization of the magnetization pinned layers in the plurality of second arrays may include a component in a second direction different from the first direction. The fixation may include first fixation of fixing the direction of the magnetization of the initial magnetization pinned layer of each of some initial magnetoresistive elements to be the some magnetoresistive elements to later form the plurality of first arrays of the plurality of initial magnetoresistive elements and second fixation of fixing the direction of the magnetization of the initial magnetization pinned layer of each of some other initial magnetoresistive elements to be the some magnetoresistive elements to later form the plurality of second arrays of the plurality of initial magnetoresistive elements. The second fixation may be performed after the first fixation.

When the fixation fixes the direction of the magnetization of each of the initial magnetization pinned layers by using laser light and an external magnetic field, the element formation may further include forming a plurality of initial arrays to later become the plurality of arrays. Some initial arrays of the plurality of initial arrays may be irradiated with the laser light at a same time. The plurality of arrays may be arranged at equal intervals irrespective of the plurality of dies. The some arrays may be arranged in the same positional relationship for each of the plurality of dies.

When the fixation fixes the direction of the magnetization of each of the initial magnetization pinned layers by using laser light and an external magnetic field, an area of a planar shape of each of the plurality of arrays may be smaller than an area of a planar shape of each of the plurality of dies. An area of a region of a stack including the plurality of initial magnetoresistive elements irradiated with the laser light at a same time in the fixation may be larger than the area of the planar shape of each of the plurality of dies.

When the fixation fixes the direction of the magnetization of each of the initial magnetization pinned layers by using laser light and an external magnetic field, an area of a planar shape of each of the plurality of arrays may be smaller than the area of the planar shape of each of the plurality of dies. An area of a region of a stack including the plurality of initial magnetoresistive elements irradiated with the laser light at a same time in the fixation may be larger than the area of the planar shape of each of the plurality of arrays and may be smaller than the area of the planar shape of each of the plurality of dies.

In the wafer of the disclosure, the plurality of dies and the some arrays are arranged in a manner that the second pitch is not larger than the first pitch. The some arrays and the some magnetoresistive elements are arranged in a manner that the third pitch is not larger than the second pitch. With these, according to the disclosure, the direction of the magnetization of the magnetization pinned layers can be fixed efficiently.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A wafer to be used for manufacturing a plurality of magnetic sensors, the wafer comprising:
a plurality of magnetoresistive elements arranged regularly;
a plurality of arrays each including some magnetoresistive elements of the plurality of magnetoresistive elements and arranged regularly; and
a plurality of dies sectioned regularly to correspond to the plurality of respective magnetic sensors and each including some arrays of the plurality of arrays, wherein
each of the plurality of magnetoresistive elements includes a magnetization pinned layer having magnetization whose direction is fixed, a free layer having magnetization whose direction is variable according to an applied magnetic field, and a gap layer arranged between the magnetization pinned layer and the free layer,
the directions of the magnetization of the magnetization pinned layers are defined for each of the plurality of arrays,
the plurality of dies are arranged at a first pitch,
the some arrays are arranged at a second pitch in each of the plurality of dies and electrically connected to configure a bridge circuit,
the some magnetoresistive elements are arranged at a third pitch in each of the plurality of arrays and electrically connected to each other,
the plurality of dies and the some arrays are arranged in a manner that the second pitch is not larger than the first pitch, and
the some arrays and the some magnetoresistive elements are arranged in a manner that the third pitch is not larger than the second pitch.

2. The wafer according to claim 1, wherein the some arrays and the some magnetoresistive elements are arranged in a manner that the second pitch is larger than the third pitch.

3. The wafer according to claim 2, wherein, by assuming that m and n are each an integer larger than 1, the some magnetoresistive elements are arranged in m rows by n columns in each of the plurality of arrays.

4. The wafer according to claim 1, wherein the some arrays and the some magnetoresistive elements are arranged in a manner that the second pitch is equal to the third pitch.

5. The wafer according to claim 1, wherein the plurality of dies and the some arrays are arranged in a manner that the first pitch is larger than the second pitch.

6. The wafer according to claim 1, wherein the plurality of arrays are arranged at equal intervals irrespective of the plurality of dies.

7. The wafer according to claim 1, wherein the some arrays are arranged in a same positional relationship for each of the plurality of dies.

8. A magnetic sensor manufacturing method of manufacturing a plurality of magnetic sensors by using a wafer, the wafer including
a plurality of magnetoresistive elements arranged regularly;
a plurality of arrays each including some magnetoresistive elements of the plurality of magnetoresistive elements and arranged regularly; and
a plurality of dies sectioned regularly to correspond to the plurality of respective magnetic sensors and each including some arrays of the plurality of arrays,
each of the plurality of magnetoresistive elements including a magnetization pinned layer having magnetization whose direction is fixed, a free layer having magnetization whose direction is variable according to an applied magnetic field, and a gap layer arranged between the magnetization pinned layer and the free layer,
the directions of the magnetization of the magnetization pinned layers being defined for each of the plurality of arrays,
the plurality of dies being arranged at a first pitch,
the some arrays being arranged at a second pitch in each of the plurality of dies and electrically connected to configure a bridge circuit,
the some magnetoresistive elements being arranged at a third pitch in each of the plurality of arrays and electrically connected to each other,
the plurality of dies and the some arrays being arranged in a manner that the second pitch is not larger than the first pitch,
the some arrays and the some magnetoresistive elements being arranged in a manner that the third pitch is not larger than the second pitch,
the manufacturing method comprising:
producing the wafer;
dicing the plurality of dies from the wafer to produce a plurality of chips; and
producing the plurality of magnetic sensors from the plurality of chips, wherein
the producing of the wafer includes
element formation of forming the plurality of magnetoresistive elements and the plurality of arrays and
forming wiring for connecting the plurality of magnetoresistive elements, and
the element formation includes
forming a plurality of initial magnetoresistive elements each including an initial magnetization pinned layer to later be the magnetization pinned layer and the free layer and
fixation of fixing a direction of the magnetization of the initial magnetization pinned layer of each of the plurality of initial magnetoresistive elements.

9. The magnetic sensor manufacturing method according to claim 8, wherein the fixation fixes the direction of the magnetization of the initial magnetization pinned layer by using laser light and an external magnetic field.

10. The magnetic sensor manufacturing method according to claim 9, wherein
the plurality of arrays include a plurality of first arrays and a plurality of second arrays,
the magnetization of the magnetization pinned layers in the plurality of first arrays include a component in a first direction, and
the magnetization of the magnetization pinned layers in the plurality of second arrays include a component in a second direction different from the first direction,
the fixation includes
first fixation of fixing the direction of the magnetization of the initial magnetization pinned layer of each of some initial magnetoresistive elements to be the some magnetoresistive elements to later form the plurality of first arrays of the plurality of initial magnetoresistive elements and
second fixation of fixing the direction of the magnetization of the initial magnetization pinned layer of each of some other initial magnetoresistive elements to be the some magnetoresistive elements to later form the plurality of second arrays of the plurality of initial magnetoresistive elements, and
the second fixation is performed after the first fixation.

11. The magnetic sensor manufacturing method according to claim 9, wherein
the element formation further includes forming a plurality of initial arrays to later be the plurality of arrays, and
some initial arrays of the plurality of initial arrays are irradiated with the laser light at a same time.

12. The magnetic sensor manufacturing method according to claim 11, wherein the plurality of arrays are arranged at equal intervals irrespective of the plurality of dies.

13. The magnetic sensor manufacturing method according to claim 11, wherein the some arrays are arranged in a same positional relationship for each of the plurality of dies.

14. The magnetic sensor manufacturing method according to claim 9, wherein
an area of a planar shape of each of the plurality of arrays is smaller than an area of a planar shape of each of the plurality of dies, and
an area of a region of a stack including the plurality of initial magnetoresistive elements irradiated with the laser light at a same time in the fixation is larger than the area of the planar shape of each of the plurality of dies.

15. The magnetic sensor manufacturing method according to claim 9, wherein
an area of a planar shape of each of the plurality of arrays is smaller than an area of a planar shape of each of the plurality of dies, and
an area of a region of a stack including the plurality of initial magnetoresistive elements irradiated with the laser light at a same time in the fixation is larger than the area of the planar shape of each of the plurality of arrays and is smaller than the area of the planar shape of each of the plurality of dies.
